(19) United States
(12) Patent Application Publication
(10) Pub. No.: US 2015/0349000 A1
(43) Pub. Date: Dec. 3, 2015

(54) FABRICATION OF TRANSISTOR WITH HIGH DENSITY STORAGE CAPACITOR

(71) Applicant: QUALCOMM MEMS Technologies, Inc., San Diego, CA (US)

(72) Inventors: Cheonhong Kim, San Diego, CA (US); Tze-Ching Fung, San Diego, CA (US); Jae Hyeong Seo, Pleasanton, CA (US); Tallis Young Chang, San Diego, CA (US)

(21) Appl. No.: 14/512,948

(22) Filed: Oct. 13, 2014

Related U.S. Application Data
(60) Provisional application No. 62/004,590, filed on May 29, 2014.

(51) Int. Cl. H01L 27/13; H01L 49/02; H01L 29/66

(52) U.S. Cl. CPC H01L 27/13; H01L 29/6675; H01L 28/40

(57) ABSTRACT

This disclosure provides apparatuses and methods for fabricating TFTs and storage capacitors on a substrate. In one aspect, an apparatus includes a TFT and a storage capacitor, where the TFT includes a first metal layer, a second metal layer, and a semiconductor layer, where the semiconductor layer is protected by a first etch stop layer and a second etch stop layer. The storage capacitor includes the second etch stop layer as a dielectric between the first metal layer and the second metal layer. In another aspect, an apparatus includes a TFT and a storage capacitor, where the TFT includes a first metal layer, a dielectric layer, and a semiconductor layer, where the semiconductor layer is protected by an etch stop layer. The storage capacitor includes the dielectric layer as a dielectric between the first metal layer and the semiconductor layer.

### PRIORITY DATA

This patent document claims priority to co-pending and commonly assigned U.S. Provisional Patent Application No. 62/004,590, titled “Fabrication of Transistor With High Density Storage Capacitor”, by Kim et al., filed on May 29, 2014 (Attorney Docket No. 144819P1/QUALP253P), which is hereby incorporated by reference in its entirety and for all purposes.

### TECHNICAL FIELD

This disclosure relates to charge storage and transfer elements, and more particularly to fabrication of transistor structures and storage capacitors in electromechanical systems and devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In EMS driven display panels and other voltage/charge driven pixel displays, such as liquid crystal displays (LCDs), it is often desirable to update the display elements for an entire frame synchronously. In a conventional synchronous frame update scheme, the pixel or display element data for each frame is written or scanned into charge storage elements (such as storage capacitors) at each corresponding pixel, one row of pixels at a time. The charge storage elements need to preserve the stored data while other rows are addressed until the new data is scanned in again. This method of operation can require high capacitance for storing data while driving the display elements.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a substrate having a first region and a second region adjacent to the first region, a thin film transistor (TFT) on the first region of the substrate, and a storage capacitor on the second region of the substrate. The TFT includes a first metal layer on the substrate, a semiconductor layer over the first metal layer and having a channel region between a source region and a drain region, a first etch stop layer on the semiconductor layer, a second etch stop layer on the first etch stop layer, and a second metal layer contacting the source region and the drain region of the semiconductor layer. The storage capacitor includes the first metal layer on the substrate, the second etch stop layer on the first metal layer over the second region of the substrate, and the second metal layer on the second etch stop layer over the second region of the substrate.

In some implementations, the apparatus further includes a dielectric layer between the first metal layer and the semiconductor layer over the first region of the substrate, where each of the dielectric layer and the first etch stop layer includes silicon dioxide. In some implementations, the semiconductor layer includes indium-gallium-zinc-oxide (InGaZnO). In some implementations, the second etch stop layer has a thickness less than about 100 nm. In some implementations, the apparatus further includes one or more first openings extending through the first etch stop layer to the first metal layer on the second region of the substrate, and one or more second openings extending through the first etch stop layer and the second etch stop layer to the source region and the drain region of the semiconductor layer. The second metal layer can substantially fill the one or more first openings and the one or more second openings. The second etch stop layer can be conformal along sidewalls of the one or more first openings extending through the first etch stop layer.

Another innovative aspect of the subject matter described in this disclosure can be implemented in an apparatus include a substrate having a first region and a second region adjacent to the first region, a TFT on the first region of the substrate, and a storage capacitor on the second region of the substrate. The TFT includes a first metal layer on the substrate, a dielectric layer on the first metal layer, a semiconductor layer on the dielectric layer, and an etch stop layer on the semiconductor layer. The storage capacitor includes the first metal on the substrate, the dielectric layer on the first metal layer, the semiconductor layer on the dielectric layer over the second region of the substrate and having an exposed region and an unexposed region, and the etch stop layer on the unexposed region of the semiconductor layer, and a second metal layer on the exposed region of the semiconductor layer.

In some implementations, each of the dielectric layer and the etch stop layer includes silicon dioxide. In some implementations, the semiconductor layer includes InGaZnO. In some implementations, the dielectric layer has a thickness between about 50 nm and about 500 nm. In some implementations, the semiconductor layer has a channel region between a source region and a drain region over the first region of the substrate, and the apparatus further includes one or more first openings extending through the etch stop layer to the exposed region of the semiconductor layer, and one or more second openings extending through the etch stop layer to the source region and the drain region of the semiconductor layer. The second metal layer contacts the source region and the drain region of the semiconductor layer, where the second metal layer substantially fills the one or more first openings and the one or more second openings. The exposed region of the semiconductor layer in contact with the second metal layer is electrically conductive.

Another innovative aspect of the subject matter described in this disclosure can be implemented in a method of manufacturing a TFT and a storage capacitor on a substrate. The method includes providing a substrate having a first region and a second region adjacent to the first region, forming a first metal layer on the first region and the second region of the substrate, forming a dielectric layer on the first metal layer over the first region and the second region of the substrate, forming a semiconductor layer on the dielectric layer over the first region of the substrate and having a channel region between a source region and a drain region, forming a first etch stop layer on the semiconductor layer over the first region of the substrate and on the dielectric layer over the second region of the substrate, forming one or more first openings extending through the etch stop layer and the dielectric layer to the first metal layer over the second region of the substrate, forming a second etch stop layer on the first etch stop layer over the first region of the substrate and in the one or more first openings and on the first metal layer over the second region of the substrate, forming one or more second openings extending through the second etch stop layer and the first etch stop layer to the source region and the drain region of the semiconductor layer, and forming a second metal layer on the second etch stop layer in the one or more first openings and on the source region and the drain region of the semiconductor layer in the one or more second openings.

In some implementations, the second metal layer on the source region is configured to output an output signal to drive an EMS display element, and the second metal layer on the drain region of the semiconductor layer is configured to receive an input signal to cause charge to be accumulated along the second metal layer over the second region of the substrate. In some implementations, the second etch stop layer has a thickness of less than about 100 nm.

Another innovative aspect of the subject matter described in this disclosure can be implemented in a method of manufacturing a TFT and a storage capacitor on a substrate. The method includes providing a substrate having a first region and a second region adjacent to the first region, forming a first metal layer on the first region and the second region of the substrate, forming a dielectric layer on the first metal layer over the first and the second region of the substrate, forming a semiconductor layer on the dielectric layer over the first region and the second region of the substrate and having a channel region between a source region and a drain region, forming an etch stop layer on the semiconductor layer over the first region and the second region of the substrate, forming one or more first openings extending through the etch stop layer to expose a portion of the semiconductor layer over the second region of the substrate, forming one or more second openings extending through the etch stop layer to expose the source region and the drain region of the semiconductor layer over the first region of the substrate, and forming a second metal layer on the semiconductor layer in the one or more first openings and on the semiconductor layer in the one or more second openings, where the semiconductor layer in contact with the second metal layer in the one or more first openings is electrically conductive.

In some implementations, the second metal layer at the source region is configured to output an output signal to drive an EMS display element and the second metal layer at the drain region is configured to receive an input signal to cause charge to be accumulated along the semiconductor layer over the second region of the substrate. In some implementations, the dielectric layer has a thickness between about 50 nm and about 500 nm.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIGS. 3A and 3B are system block diagrams illustrating a display device that includes a plurality of IMOD display elements.

FIG. 4 is an example of a circuit diagram illustrating a pixel for a display device.

FIG. 5 is an example of a cross-sectional diagram illustrating an apparatus including a thin-film transistor (TFT) and a storage capacitor, a thickness of the storage capacitor defined by a total thickness of an etch stop layer and a dielectric layer according to some implementations.

FIG. 6 is an example of a cross-sectional diagram illustrating an apparatus including a TFT and a storage capacitor, a thickness of the storage capacitor defined by a thickness of a dielectric layer according to some implementations.

FIG. 7 is an example of a cross-sectional diagram illustrating an apparatus including a TFT and a storage capacitor, a thickness of the storage capacitor defined by a thickness of a second etch stop layer according to some implementations.

FIG. 8 is an example of a cross-sectional diagram illustrating an apparatus including a TFT and a storage capacitor, a thickness of the storage capacitor defined by a thickness of a dielectric layer and a semiconductor layer serving as an electrode according to some implementations.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Various implementations described herein relate to the fabrication of transistor structures and storage elements on a substrate or on an EMS display element. Transistor structures, such as thin film transistors (TFTs), and storage elements, such as storage capacitors, may be fabricated concurrently. Deposition of metal layers for a TFT can be used as top and bottom electrodes for a storage capacitor. Deposition of dielectric layers for the TFT, including gate insulators and etch stop layers, can be used as a dielectric material between the top and bottom electrodes of the storage capacitor. Capacitance can be increased for a storage capacitor by reducing a thickness of the dielectric material. The thickness of the dielectric material in implementations described herein are not tied to the thickness of both the etch stop layer and the gate insulator of the TFT. Therefore, one implementation of an apparatus can include a TFT and a storage capacitor, where the TFT includes a first metal layer, a dielectric layer on the first metal layer, a semiconductor layer on the dielectric layer, a first etch stop layer on the semiconductor layer, a second etch stop layer on the first etch stop layer, and a second metal layer contacting the semiconductor layer at source and drain regions of the semiconductor layer. The storage capacitor includes the first metal layer as a bottom electrode, the second metal layer as the top electrode, and the second etch stop layer as a dielectric material between the top and bottom electrode. Another implementation of an apparatus can include a TFT and a storage capacitor, where the TFT includes a first metal layer, a dielectric layer on the first metal layer, a semiconductor layer on the dielectric layer, an etch stop layer on the semiconductor layer, and a second metal layer contacting the semiconductor layer at source and drain regions of the semiconductor layer. The storage capacitor includes the first metal layer as a bottom electrode, the semiconductor layer in electrical connection with the second metal layer as the top electrode, and the dielectric layer as a dielectric material between the top and bottom electrode.

Particular implementations of the subject matter described in this disclosure can be implemented to realize one or more of the following potential advantages. Reducing the thickness of the dielectric material for the storage capacitor of a display device can increase the capacitance of the storage capacitor, and the increased capacitance can improve the performance of the display device. For example, more data charge can be stored in each pixel while driving the display elements of the display device. Therefore, it is possible to reduce the update rate, such as for low power operations. Increasing capacitance of the storage capacitor without having to increase the surface area of the electrodes of the storage capacitor can improve the resolution of the display device because the storage capacitor does not have to occupy as much of the display area. Moreover, increasing the capacitance of the storage capacitor without having to substitute the dielectric material with a costly material can reduce the manufacturing cost of the display device. Co-fabricating the TFT and the storage capacitor can reduce the manufacturing cost by reducing the number of processing steps. In some implementations, the manufacturing costs can be further reduced by using the semiconductor layer as an etch stopper for the storage capacitor and by using the gate insulator as the dielectric material for the storage capacitor.

An example of a suitable EMS or MEMS device or apparatus, to which the described implementations of the TFT and storage capacitor may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

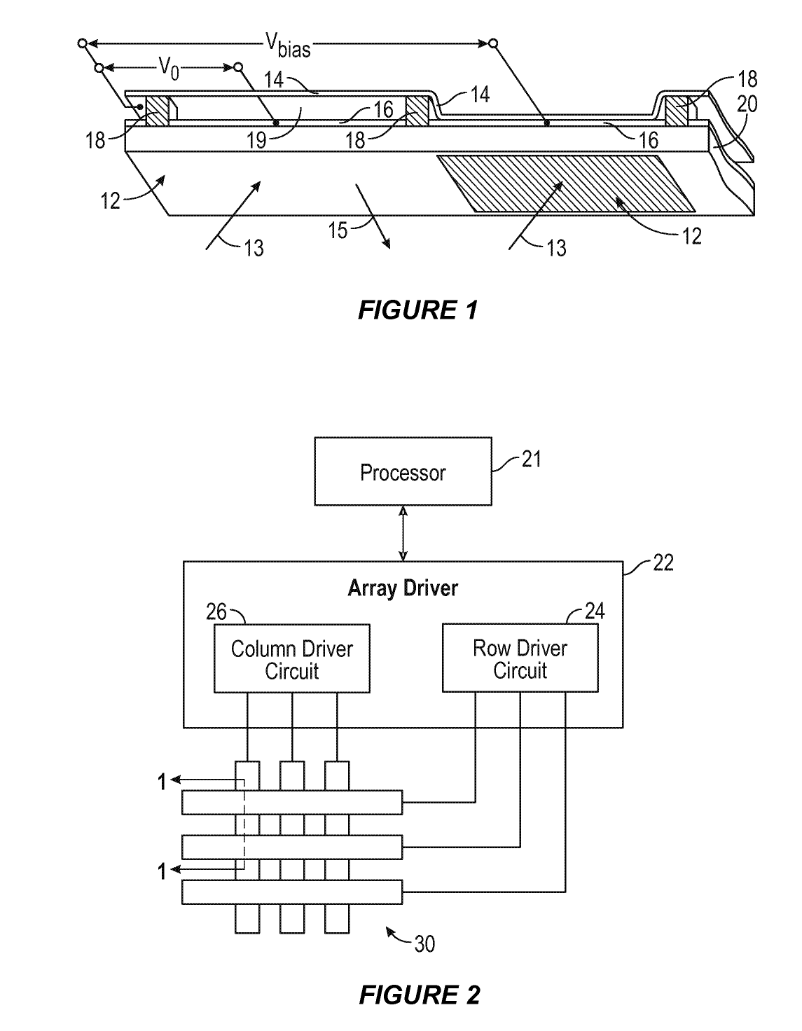

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

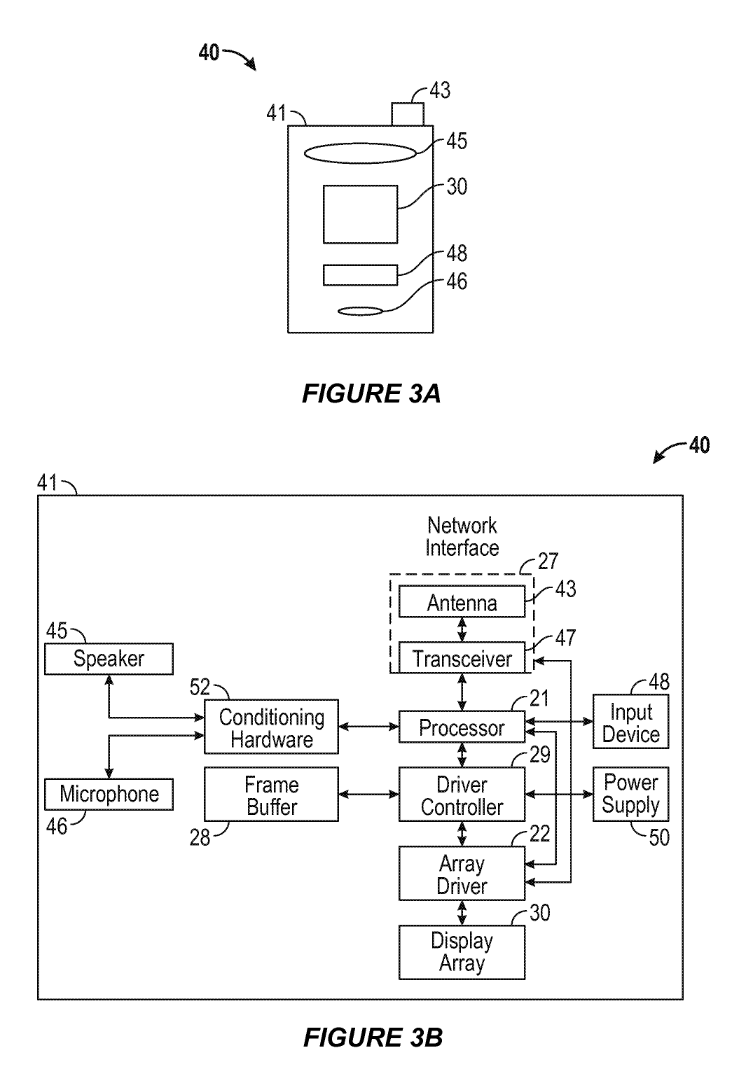

FIGS. 3A and 3B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 3A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 3A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As discussed above, a display device can include an array of display elements, which can be referred to as pixels. Some displays can include hundreds, thousands, or millions of pixels arranged in hundreds or thousands of rows and hundreds and thousands of columns. Each pixel can be driven by one or more TFTs. The TFT is a particular type of field-effect transistor (FET) in which a semiconducting layer as well as one or more dielectric insulating layers and metallic layers are formed over a substrate.

Generally, a TFT can include a source region, a drain region, and a channel region in the semiconductor layer. In other words, a TFT can be a three-terminal device that includes a source terminal, a drain terminal, and a gate terminal for modulating the conductivity of the channel.

Display elements (e.g., pixels) in an EMS display device may be arranged in an array such as a two-dimensional grid and addressed by circuits associated with the rows and columns of the array. Row driver circuits may drive the gates of transistor switches that select a particular row to be addressed, and common driver circuits may provide a bias to a given row of display elements that may be synchronously updated with a row refresh.

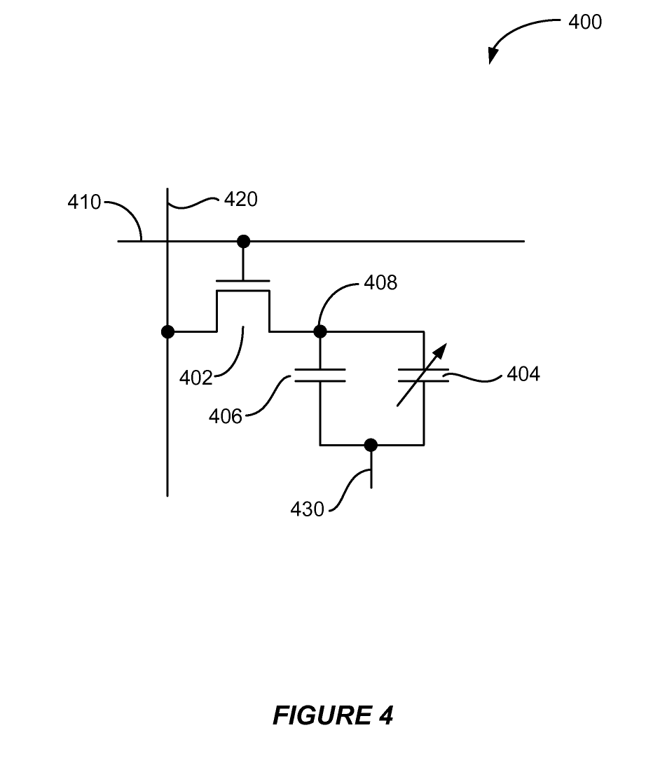

FIG. 4 is an example of a circuit diagram illustrating a pixel for a display device. In some implementations, the circuit diagram can show a pixel 400 for an active-matrix IMOD display, where each pixel can be organized in an array to form the display. In FIG. 4, each pixel 400 includes a transistor switch 402, an EMS display element 404, and a storage capacitor 406. The transistor switch 402 can be a TFT. The TFT may be included in row and/or column driver circuits for addressing the EMS display elements 404.

As an example, the pixel 400 may be provided with a row signal from a row electrode 410, a column signal from column electrode 420, and a common signal from a common electrode 430. The implementation of the pixel 400 may include a variety of different designs. As illustrated in the example in FIG. 4, the transistor switch 402 can have a gate coupled to the row electrode 410, and column electrode 420 provided to a drain. A description of creating a frame of an image for a pixel with respect to row, common, and column electrodes may be found in U.S. application Ser. No. 13/909,839, titled “Reducing Floating Node Leakage Current with a Feedback Transistor” (attorney docket no.: QUALP191/130643), which is hereby incorporated by reference in its entirety and for all purposes.

In one mode of operation, a row driving circuit 410 can turn on one row at a time in an EMS display device. A column driving circuit 420 can provide data to each pixel 400 of the EMS display device. When the data is provided from the column driving circuit 420, the data can be stored in a pixel 400 using a storage capacitor 406. As the row driver circuits 410 address each row, the storage capacitor 406 can store the data for the pixel 400 in the previously addressed row. For example, the pixel 400 can continue to display the correct color because the data is stored in the storage capacitor 406. The data may be held at the pixel 400 in a particular row until the row is addressed again, upon which the row of pixels 400 are synchronously updated with a row refresh. The ability to store data at the pixel 400 and to drive an EMS display element 404 in a pixel 400 can be directly tied to the capacitance of a storage capacitor 406.

It is desirable to achieve a sufficient capacitance of a storage capacitor for a display device. A higher capacitance may be needed depending on the requirements of the display device. For example, some display devices may incorporate EMS display elements, and a higher capacitance may be required to not only store data at each pixel but to also drive the EMS display elements. Typically, an increased capacitance can be achieved by increasing the size of the storage capacitor, such as by increasing the area of the electrodes of the storage capacitor. However, this can add to the size of the pixel and reduce the resolution of the display. Alternatively, an increased capacitance can be achieved by substituting the dielectric material of the storage capacitor with a material having a high dielectric constant. However, this can add to the cost of manufacturing the display device.

Hardware and data processing apparatus may be associated with EMS structures. Such hardware and data processing apparatus may include a transistor switch, such as a TFT. In some implementations of display devices, such as LCDs, OLEDs, and EMS display devices, a pixel may include a storage capacitor and at least one TFT to maintain stored charge or voltage during a frame time and/or to speed up device response time. In manufacturing TFTs, an etch stop layer may protect a semiconductor layer during one or more etching steps. For example, an oxide semiconductor layer may be vulnerable to damage by dry etching (e.g., plasma etching) or wet etching. In some implementations, the etch stop layer may need to be thick enough to protect the semiconductor layer from etch attack. However, the thickness of the etch stop layer may be tied to the thickness of the dielectric layer in the storage capacitor, including when the storage capacitor is fabricated at the same time as the TFT. Thus, the etch stop layer may be too thick to provide a desired capacitance for the storage capacitor.

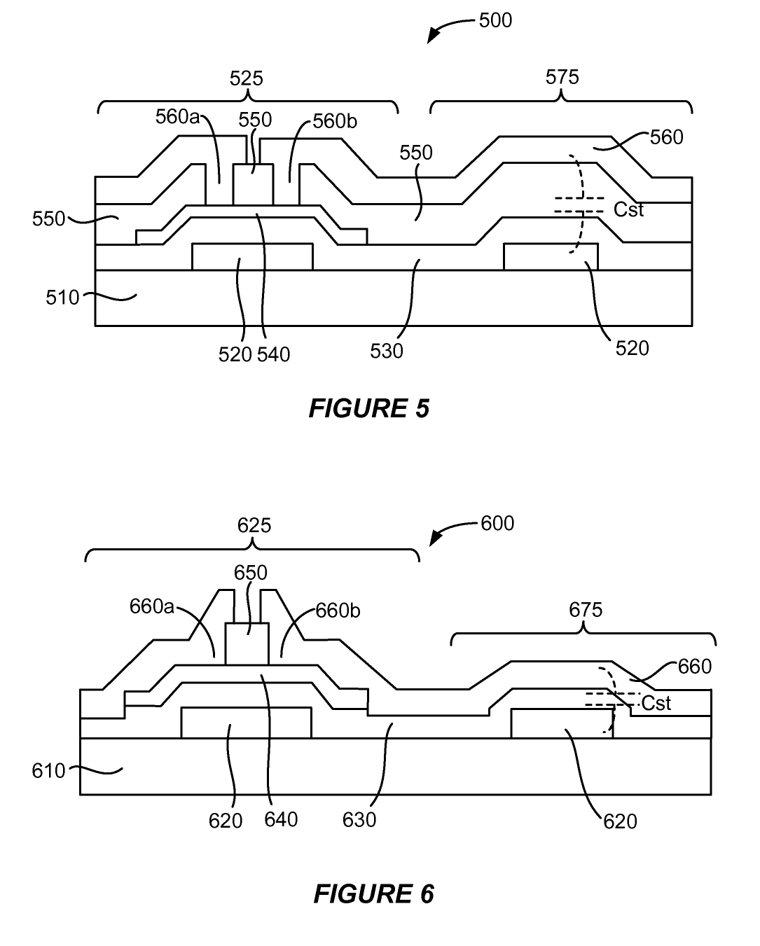

FIG. 5 is an example of a cross-sectional diagram illustrating an apparatus 500 including a TFT 525 and a storage capacitor 575, a thickness of the storage capacitor 575 defined by a total thickness of an etch stop layer 550 and a dielectric layer 530 according to some implementations. In some implementations, the TFT 525 and the storage capacitor 575 may be co-fabricated on a substrate 510, meaning that the TFT 525 and the storage capacitor 575 may be formed at the same time. Furthermore, the TFT 525 and the storage capacitor 575 may be formed using the same processing steps. In some implementations, FIG. 5 may represent a pixel of a display device, where the pixel includes the TFT 525 and the storage capacitor 575. The TFT 525 and the storage capacitor 575 can be disposed over a fabricated display element, such as an EMS display element (not shown). In some implementations, FIG. 5 may not represent a pixel of a display device, and so the TFT 525 and the storage capacitor 575 may be disposed outside of an EMS display element. For example, the TFT 525 and the storage capacitor 575 can be disposed on a substrate 510, such as a glass substrate.

In FIG. 5, a TFT 525 may be formed on the left-hand side of the cross-sectional diagram and a storage capacitor 575 may be formed on the right-hand side of the cross-sectional diagram. As will be understood by one having ordinary skill in the art, the term “formed” is used herein to refer to one or more of deposition, patterning, masking, and etching processes. An apparatus 500 can include a substrate 510 having a first region and a second region adjacent to the first region. For example, the left-hand side of the apparatus 500 can include the first region and the right-hand side of the apparatus 500 can include the second region. In some implementations, the first region can represent the region on the substrate 510 in which the TFT 525 is fabricated, and the second region can represent the region on the substrate 510 in which the storage capacitor 575 is fabricated.

As illustrated in FIG. 5, a first metal layer 520 can be formed on the first region and the second region of the substrate 510. In some implementations, the first metal layer 520 can simultaneously serve as a gate for the TFT 525 and as one of the electrodes for the storage capacitor 575. The first metal layer 520 may be patterned so that a portion of the first metal layer 520 on the left-hand side is spaced apart from another portion of the first metal layer 520 on the right-hand side. A dielectric layer 530 can be formed on the first metal layer 520 over the first region and the second region of the substrate 510. The dielectric layer 530 may serve as a gate insulator for the TFT 525 and as part of a dielectric material between electrodes for the storage capacitor 575.

A semiconductor layer 540, such as an oxide semiconductor layer, can be formed on the dielectric layer 530. The semiconductor layer 540 may be patterned to remove the semiconductor layer 540 over the second region of the substrate 510, but leave the semiconductor layer 540 over the first region of the substrate 510 intact.

A protective layer or etch stop layer 550 can be formed on the semiconductor layer 540 over the first region of the substrate 510 and on the dielectric layer 530 over the second region of the substrate 510. The etch stop layer 550 may be made of a dielectric material, such as silicon dioxide. Portions of the etch stop layer 550 over the first region may be removed to expose one or more portions of the semiconductor layer 540.

A second metal layer 560 may be formed on the exposed portions of the exposed semiconductor layer 540. In some implementations, the semiconductor layer 540 may include source region and a drain region, and a channel region between the source region and the drain region. The second metal layer 560 may be contacting the exposed portions of the semiconductor layer 540 at the source region and at the drain region. In some implementations, the second metal layer 560 may include a source terminal 560a and a drain terminal 560b, where the source terminal 560a contacts the source region of the semiconductor layer 540 and the drain terminal 560b contacts the drain region of the semiconductor layer 540. The second metal layer 560 also may be formed on the etch stop layer 550 over the second region of the substrate 510. Thus, the second metal layer 560 can simultaneously serve as the source/drain metal for the TFT 525 and as one of the electrodes for the storage capacitor 575.

As illustrated in FIG. 5, the apparatus 500 can include the TFT 525 over the first region of the substrate 510 and the storage capacitor 575 over the second region of the substrate 510. The storage capacitor 575 can include the first metal layer 520, the second metal layer 560, and the dielectric layer 530 and the etch stop layer 550 stacked between the first metal layer 520 and the second metal layer 560. The etch stop layer 550 and the dielectric layer 530 are stacked in series to provide a dielectric material between two electrodes of the storage capacitor 575. The capacitance Cst of the storage capacitor may correspond to the total thickness of both the dielectric layer 530 and the etch stop layer 550. While the etch stop layer 550 may serve to protect the TFT 525, the etch stop layer 550 also may add to the thickness of the dielectric layer 530 of the storage capacitor 575. In some implementations, the etch stop layer 550 has a thickness greater than about 100 nm. The etch stop layer 550 may have a sufficient thickness to protect the TFT 525 from etch processing steps that may otherwise adversely affect the semiconductor layer 540. However, the added thickness from the etch stop layer 550 may reduce the capacitance Cst of the storage capacitor 575. If the thickness of the etch stop layer 550 were reduced, the etch stop layer 550 may not have a sufficient thickness to protect the TFT 525.

Thus, one implementation can remove the etch stop layer 550 from the second region of the substrate 510 to reduce the distance between the two electrodes of the storage capacitor 575. As a result, the capacitor density of the storage capacitor 575 may be increased without compromising protection of the semiconductor layer 540 over the first region of the substrate 510.

FIG. 6 is an example of a cross-sectional diagram illustrating an apparatus 600 including a TFT 625 and a storage capacitor 675, a thickness of the storage capacitor 675 defined by a thickness of a dielectric layer 630 according to some implementations. In contrast to FIG. 5, the etch stop layer 650 over the second region of the substrate 610 is removed. Therefore, the etch stop layer 650 may serve to protect the TFT 625 while the removal of the etch stop layer 650 from the storage capacitor 675 may decrease the thickness of dielectric material 630 in the storage capacitor 675.

In FIG. 6, an apparatus 600 includes a substrate 610 having a first region and a second region adjacent to the first region. The first region can represent the region of the apparatus 600 in which the TFT 625 is fabricated, and the second region can represent the region of the apparatus 600 in which the storage capacitor 675 is fabricated. A first metal layer 620 can be formed on the first region and the second region of the substrate 610. In some implementations, the first metal layer 620 may simultaneously serve as a gate for the TFT 625 and as one of the electrodes of the storage capacitor 675. The first metal layer 620 may be patterned so that a portion of the first metal layer 620 on the left-hand side is spaced apart from another portion of the first metal layer 620 on the right-hand side. A dielectric layer 630 is formed on the first metal layer 620 over the first region and the second region of the substrate 610. Though not shown in FIG. 6, a portion of the dielectric layer 630 over the first region of the substrate 610 may be removed to expose a portion of the first metal layer 620. In some implementations, a portion of the dielectric layer 630 may be removed to form vias extending towards the first metal layer 620. This allows for electrical interconnection to be made between the first metal layer 620 and a second metal layer 660. Therefore, a via can be formed to provide an electrically conductive pathway connecting a source/drain of the TFT 625 with a gate of the TFT 625.

A semiconductor layer 640, such as an oxide semiconductor layer, may be formed on the dielectric layer 630. The semiconductor layer 640 may be patterned to remove the semiconductor layer 640 over the second region of the substrate 610, but leave the semiconductor layer 640 over the first region of the substrate 610.

A protective layer or etch stop layer 650 can be formed on the semiconductor layer 640. The etch stop layer 650 may be made of a dielectric material, such as silicon dioxide. The etch stop layer 650 may be patterned so that the etch stop layer 650 over the second region of the substrate 610 is removed. Moreover, portions of the etch stop layer 650 over the first region may be removed to expose portions of the semiconductor layer 640. The semiconductor layer 640 may include source region, a drain region, and a channel region between the source region and the drain region. After patterning the etch stop layer 650, the remainder of the etch stop layer 650 over the first region of the substrate 610 may be disposed on at least the channel region of the semiconductor layer 640.

A second metal layer 660 may be formed on the exposed portions of the semiconductor layer 640 and on the dielectric layer 630. In the first region, the second metal layer 660 may be contacting the exposed portions of the semiconductor layer 640 at the source region and at the drain region. In some implementations, the second metal layer may include a source terminal 660a and a drain terminal 660b, where the source terminal 660a contacts the source region of the semiconductor layer 640 and the drain terminal 660b contacts the drain region of the semiconductor layer 640. In some implementations, the second metal layer 660 can simultaneously serve as the source/drain metal for the TFT 625 and as one of the electrodes for the storage capacitor 675.

In FIG. 6, a thickness of the dielectric layer 630 can correspond to the capacitance Cst of the storage capacitor 675. However, the thickness of the dielectric layer 630 over the second region of the substrate 610 may not be the same as over the first region of the substrate 610. When the etch stop layer 650 is patterned, the etch stop layer 650 over the second region of the substrate 610 is removed. As a result, portions of the dielectric layer 630 over the second region of the substrate 610 may be removed in some implementations. The semiconductor layer 640 may be selective against the etching step that removes the etch stop layer 650. In some implementations, this can cause the dielectric layer 630 over the second region of the substrate 610 to be over-etched while the semiconductor layer 640 protects the underlying dielectric layer 630 over the first region of the substrate 610. Without being able to precisely control the amount of over-etching that takes place in the dielectric layer 630 over the second region of the substrate 610, the capacitance Cst of the storage capacitor 675 may be difficult to control. Thus, fabrication of a storage capacitor 675 having a precisely tuned capacitance Cst may be difficult under the aforementioned processing steps.

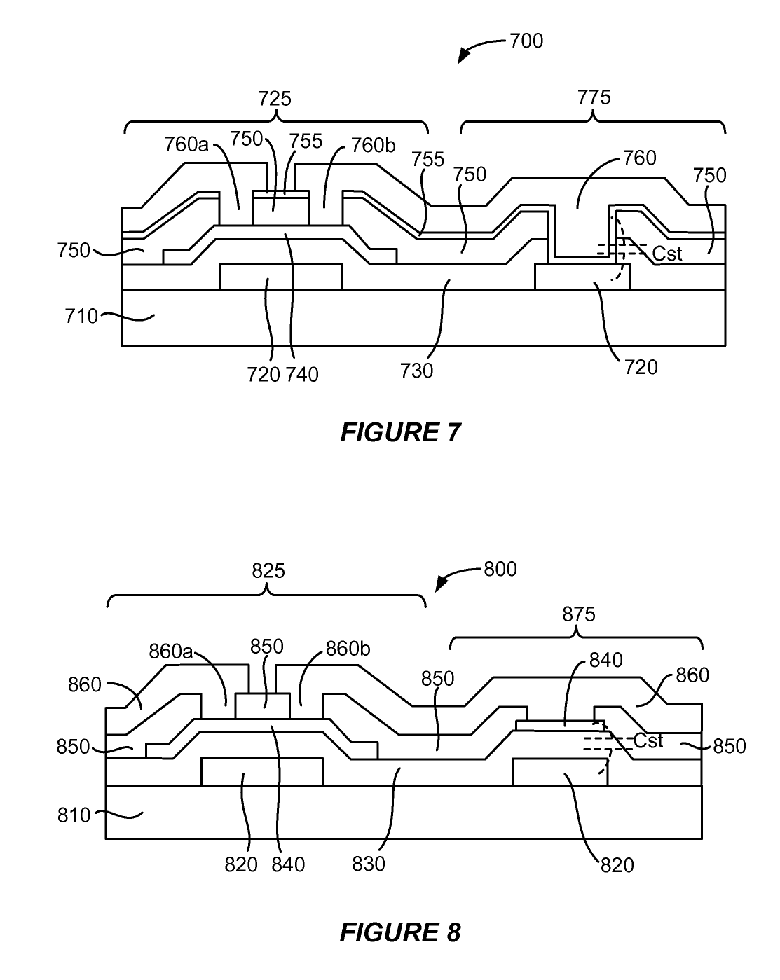

To achieve sufficient thickness for protecting a TFT and to control the thickness of the dielectric material in a storage capacitor, another implementation of an apparatus 700 including a TFT 725 and a storage capacitor 775 can be provided. FIG. 7 is an example of a cross-sectional diagram illustrating an apparatus 700 including a TFT 725 and a storage capacitor 775, a thickness of the storage capacitor 775 defined by a thickness of a second etch stop layer 755 according to some implementations. The apparatus 700 can include a substrate 710 having a first region and a second region adjacent to the first region. For example, the left-hand side of the cross-sectional diagram can include the first region of the substrate 710 and the right-hand side of the cross-sectional diagram can include the second region of the substrate 710. The apparatus 700 in FIG. 7 may be described in terms of the cross-sectional diagram and in terms of a manufacturing process for fabricating the apparatus 700.

The apparatus 700 in FIG. 7 can include a TFT 725 in the first region of the substrate 710 and a storage capacitor 775 in the second region of the substrate 710. The TFT 725 includes a first metal layer 720 on the substrate 710, a dielectric layer 730 on the first metal layer 720, a semiconductor layer 740 on the dielectric layer 730, a first etch stop layer 750 on the semiconductor layer 740, a second etch stop layer 755 on the first etch stop layer 750, and a second metal layer 760 contacting a source region and a drain region of the semiconductor layer 740. The semiconductor layer 740 can include a source region, a drain region, and a channel region between the source region and the drain region.

The storage capacitor 775 includes the first metal layer 720 on the substrate 710, the second etch stop layer 755 on the first metal layer 720, and the second metal layer 760 on the second etch stop layer 755 over the second region of the substrate 710. In some implementations, the TFT 725 and the storage capacitor 775 can be part of a pixel of a display device. For example, an EMS display element (e.g., an interferometric modulator) (not shown) can be disposed underneath the TFT 725 and the storage capacitor 775. Thus, the apparatus 700 can further include the EMS display element with the substrate 710 acting as a buffer layer over the EMS display element.

In manufacturing the apparatus 700 in FIG. 7, a substrate 710 may be provided having a first region and a second region adjacent to the first region. The substrate 710 may be any number of different substrate materials, including transparent materials and non-transparent materials. In some implementations, the substrate 710 is silicon, silicon-on-insulator (SOI), or a glass (e.g., a display glass or a borosilicate glass). A non-glass substrate can be used, such as a polycarbonate, acrylic, polyethylene terephthalate (PET), or polyether ether ketone (PEEK) substrate. In some implementations, the substrate 710 on which the TFT device is fabricated has dimensions of a few microns to hundreds of microns. The TFT 725 and the storage capacitor 775 may be co-fabricated on a substrate 710, where the TFT 725 is formed on the first region of the substrate 710 and the storage capacitor 775 is formed on the second region of the substrate 710.

The apparatus 700 can include a first metal layer 720 on the first region and the second region of the substrate. The first metal layer 720 can include any number of different metals, including aluminum (Al), copper (Cu), molybdenum (Mo), tantalum (Ta), chromium (Cr), neodymium (Nd), tungsten (W), titanium (Ti), gold (Au), nickel (Ni), and an alloy containing any of these elements. In some implementations, the first metal layer 720 can include a transparent metal oxide conducting layer, including ITO. In some implementations, the first metal layer 720 includes two or more sub-layers of different metals arranged in a stacked structure. In some implementations, the first metal layer 720 can have a thickness between about 50 nm and about 500 nm, or between about 100 nm and about 250 nm.

In manufacturing the apparatus in FIG. 7, the first metal layer 720 may be formed on the first region and the second region of the substrate 710 using any number of deposition, masking, and/or etching steps. The first metal layer 720 may be deposited using deposition processes as known by a person having ordinary skill in the art, including physical vapor deposition (PVD) processes, chemical vapor deposition (CVD) processes, and atomic layer deposition (ALD) processes. PVD processes include thermal evaporation deposition, sputter deposition and pulsed laser deposition (PLD). For example, the first metal layer 720 may include Mo and may be deposited using sputter deposition. In some implementations, the first metal layer 720 may be patterned so that a portion of the substrate 710 is exposed between the first region and the second region of the substrate. Thus, a portion of the first metal layer 720 is spaced apart from another portion of the first metal layer 720. The first metal layer 720 may be etched using a dry (e.g., plasma) etching process or a wet chemical etching process. The first metal layer 720 on the first region can serve as a gate for the TFT 725 and the first metal layer 720 on the second region can serve as an electrode for the storage capacitor 775.

The apparatus 700 can further include a dielectric layer 730 on the first metal layer 720 over the first region of the substrate 710. The dielectric layer 730 may include any number of different dielectric materials, including silicon oxide (SiO₂), aluminum oxide (Al₂O₃), hafnium oxide (HfO₂), titanium oxide (TiO₂), silicon oxynitride (SiON), or silicon nitride (SiN). In some implementations, the dielectric layer 730 includes two or more sub-layers of different dielectric materials arranged in a stacked structure. In some implementations, a thickness of the dielectric layer 730 can be between about 50 nm and about 500 nm, or between about 100 nm and about 250 nm.

In manufacturing the apparatus 700 in FIG. 7, the dielectric layer 730 may be formed on the first metal layer over the first region and the second region of the substrate 710. The dielectric layer 730 may be deposited using deposition processes as known by a person having ordinary skill in the art, including PVD processes, CVD processes including PECVD processes, and ALD processes. For example, the dielectric layer 730 may include SiO₂ deposited using a PECVD process at a processing temperature greater than about 300° C. Forming the dielectric layer 730 may include etching the dielectric layer using any suitable etching process. The dielectric layer 730 may serve as a gate insulator for the TFT 725.

The apparatus 700 can further include a semiconductor layer 740 on the dielectric layer 730 over the first region of the substrate 710. The semiconductor layer 740 can be an oxide semiconductor layer. In some implementations, the oxide semiconductor layer includes an amorphous oxide semiconductor, including indium (In)-containing, zinc (Zn)-containing, tin (Sn)-containing, hafnium (He-containing, and gallium (Ga)-containing oxide semiconductors. Specific examples of amorphous oxide semiconductors include InGaZnO, InZnO, InHfZnO, InSnZnO, SnZnO, InSnO, GaZnO, and ZnO. In some implementations, the channel region of the semiconductor layer 740 may be aligned with the patterned first metal layer 720. The channel region may be between a source region and a drain region of the semiconductor layer 740. In some implementations, the semiconductor layer 740 is about 10 nm to about 100 nm thick.

In manufacturing the apparatus 700 in FIG. 7, the semiconductor layer 740 can be formed on the dielectric layer 730 over the first region of the substrate 710. The semiconductor layer 740 can include a source region, a drain region, and a channel region between the source region and the drain region. Forming the semiconductor layer 740 can include steps of depositing, masking, and/or etching the semiconductor layer. In some implementations, the semiconductor layer 740 is deposited with a PVD process. PVD processes include PLD, sputter deposition, electron beam physical vapor deposition (e-beam PVD), and evaporative deposition. For example, the semiconductor layer 740 may include InGaZnO and may be deposited using sputter deposition. The semiconductor layer 740 may be deposited on the dielectric layer 730 over the first and the second region of the substrate 710. In some implementations, the semiconductor layer 740 may be patterned to remove the semiconductor layer 740 over the second region of the substrate 710 and expose the dielectric layer 730 over the second region of the substrate 710. The semiconductor layer 740 over the first region of the substrate 710 may remain. The semiconductor layer 740 may be etched using a dry (e.g., plasma) etching process or a wet chemical etching process, depending in part on the material of the semiconductor layer 740.

The apparatus 700 can further include a first etch stop layer 750 on the semiconductor layer 740 over the first region of the substrate 710. The first etch stop layer 750 can be made of any dielectric materials. In some implementations, the first etch stop layer 750 can be made of the same material as the dielectric layer 730. For example, the first etch stop layer 750 and the dielectric layer 730 can be made of SiO₂. In some implementations, the first etch stop layer 750 is between about 50 nm and about 500 nm thick.

In manufacturing the apparatus 700 in FIG. 7, the first etch stop layer 750 may be formed on the semiconductor layer over the first region of the substrate 710 and on the dielectric layer 730 over the second region of the substrate 710. Forming the first etch stop layer 750 can include steps of depositing, masking, and/or etching the first etch stop layer 750. The first etch stop layer 750 may be deposited using deposition processes as known by a person having ordinary skill in the art, including PVD processes, CVD processes including PECVD processes, and ALD processes. For example, the first etch stop layer 750 can include SiO₂ deposited using a PECVD process at a processing temperature less than about 250° C. Using a processing temperature of less than about 250° C. can reduce the likelihood of degradation of the underlying semiconductor layer 740.

In some implementations, one or more first openings may be formed extending through the first etch stop layer 750 and the dielectric layer 730 to the first metal layer 720 over the second region of the substrate 710. Portions of the first etch stop layer 750 and the dielectric layer 730 may be removed to expose at least some of the first metal layer 720 over the second region of the substrate 710. As mentioned above, the first metal layer 720 on the second region of the substrate 710 can act as one of the electrodes of the storage capacitor 775. The one or more first openings may be formed using etching processes as known by a person having ordinary skill in the art. For example, the first etch stop layer 750 and the dielectric layer 730 may be etched using plasma dry etching, including carbon tetrafluoromethane (CF₄) or octafluorocyclobutane (C₄F₈) as the main etching gas.

In some implementations, portions of the first etch stop layer 750 and the dielectric layer 730 that are deposited outside the first region and the second region of the substrate 710 may be etched to allow for electrical interconnection with the first metal layer 720 on the first region of the substrate 710. Though not shown in FIG. 7, removal of portions of the first etch stop layer 750 and the dielectric layer 730 outside the first region and the second region of the substrate 710 can permit an electrically conductive pathway to be formed between a source/drain and the gate.

The apparatus 700 can further include a second etch stop layer 755 on the first etch stop layer 750 over the first region of the substrate and on the first metal layer 720 over the second region of the substrate. The second etch stop layer 755 can be in the one or more first openings and conformal along sidewalls of the one or more first openings. In some implementations, the second etch stop layer 755 can be made of the same material as the first etch stop layer 750. For instance, the second etch stop layer 755 and the first etch stop layer 750 can be made of SiO₂. In some implementations, the second etch stop layer 755 can be made of a different material as the first etch stop layer 750. For example, the second etch stop layer 755 can be made of a material having a higher dielectric constant than the first etch stop layer 750. The higher dielectric constant can increase the capacitance Cst of the storage capacitor 775. For example, the second etch stop layer 755 can be made of HfO₂ or SiN while the first etch stop layer 750 can be made of SiO₂.

The combined thickness of the first etch stop layer 750 and the second etch stop layer 755 over the first region of the substrate 710 can form a protective layer in protecting the semiconductor layer 740 of the TFT 725. In some implementations, the combined thickness of the first etch stop layer 750 and the second etch stop layer 755 can be greater than about 100 nm. However, without the first etch stop layer 750 or the dielectric layer 730 over the second region of the substrate 710, the second etch stop layer 755 alone becomes the dielectric material of the storage capacitor 775, sandwiched between the first metal layer 720 and a second metal layer 760, which act as the electrodes of the storage capacitor 775. As such, a thickness of the second etch stop layer 755 can control a capacitance Cst of the storage capacitor 775. Thus, the thickness and/or material of the second etch stop layer 755 can tune the capacitance Cst of the storage capacitor 775. In some implementations, the thickness of the second etch stop layer 755 can be less than about 100 nm. This can provide for a high density storage capacitor 775.

In manufacturing the apparatus 700 in FIG. 7, the second etch stop layer 755 may be formed on the first etch stop layer 750 over the first region of the substrate 710 and in the one or more openings and on the first metal layer 720 over the second region of the substrate 710. Forming the second etch stop layer 755 can include steps of depositing, masking, and/or etching the second etch stop layer 755. The second etch stop layer 755 may be deposited using deposition processes as known by a person having ordinary skill in the art, including PVD processes, CVD processes including PECVD processes, and ALD processes. For example, the second etch stop layer 755 can include SiO₂ deposited using a PECVD process at a processing temperature less than about 250° C. In another example, the second etch stop layer 755 can include a material having a higher dielectric constant. In some implementations, when the one or more first openings are formed through the first etch stop layer 750 and the dielectric layer 730, the second etch stop layer 755 can be conformally deposited along sidewalls of the one or more first openings as well as along a top surface of the first metal layer 720. As mentioned above, the second etch stop layer 755 may serve as the dielectric material for the storage capacitor 775.

In some implementations, one or more second openings are formed extending through the second etch stop layer 755 and the first etch stop layer 750 to the source region and the drain region of the semiconductor layer 740. Portions of the second etch stop layer 755 and the first etch stop layer 750 may be removed to expose parts of the semiconductor layer 740. Removal of the portions of the second etch stop layer 755 and the first etch stop layer 750 may expose the source region and the drain region of the semiconductor layer 740. The exposed parts of the semiconductor layer 740 may serve as terminals for source and drain contacts in the TFT 725. Another part of the semiconductor layer 740 may remain covered by the first etch stop layer 750. The covered part of the semiconductor layer 740 may be aligned with the channel region of the semiconductor layer 740. Portions of the first etch stop layer 750 and the second etch stop layer 755 may be removed using etching processes as known by a person having ordinary skill in the art. For example, portions of the first etch stop layer 750 and the second etch stop layer 755 may be etched using dry etching, including CF₄ or C₄F₈ as the etchants.

The apparatus 700 may further include a second metal layer 760 on the second etch stop layer 755 in the one or more first openings and on the semiconductor layer 740 in the one or more second openings. The second metal layer 760 may be contacting the semiconductor layer 740 at the source region and the drain region. In some implementations, the second metal layer 760 may include a source terminal 760a and a drain terminal 760b, where the source terminal 760a contacts the source region of the semiconductor layer 740 and the drain terminal 760b contacts the drain region of the semiconductor layer 740.

The second metal layer 760 can include any number of different metals, including Al, Cu, Mo, Ta, Cr, Nd, W, Ti, Au, Ni, and an alloy containing any of these elements. In some implementations, the second metal layer 760 can include a transparent metal oxide conducting layer, including ITO. In some implementations, the second metal layer 760 includes two or more sub-layers of different metals arranged in a stacked structure. In some implementations, the second metal layer 760 can have a thickness between about 50 nm and about 500 nm, or between about 100 nm and about 250 nm.

In manufacturing the apparatus 700 in FIG. 7, the second metal layer 760 may be formed on the second etch stop layer 755 in the one or more openings and on the exposed portions of the semiconductor layer 740 in the one or more second openings. Forming the second metal layer 760 can include steps of depositing, masking, and/or etching the second metal layer 760. In some implementations, the second metal layer 760 is formed on the source region and the drain region of the semiconductor layer 740. The second metal layer 760 may fill or at least substantially fill the one or more first openings and the one or more second openings. The second metal layer 760 may be deposited using deposition processes as known by a person having ordinary skill in the art, including PVD processes, CVD processes, and ALD processes. In some implementations in which the second metal layer 760 is formed using a PVD process, the PVD process is sputter deposition, e-beam PVD, or evaporative deposition. The second metal layer 760 may be etched using a dry (e.g., plasma) etching process or a wet chemical etching process. The second metal layer 760 can simultaneously serve as the source/drain metal for the TFT 725 and as one of the electrodes for the storage capacitor 775.

With respect to the TFT 725, the second metal layer 760 contacting the source region of the semiconductor layer 740 can be configured to output an output signal, where the output signal can be configured to drive a display element, such as an EMS display element. With respect to the storage capacitor 775, the second metal layer 760 contacting the semiconductor layer 740 at the drain region can be configured to receive an input signal, where the input signal can cause charge to be accumulated along the second metal layer 760 on the second etch stop layer 755 over the second region of the substrate 710. The input signal can store data in the storage capacitor 775 for the display device.

The implementation as illustrated in FIG. 7 can independently control the thickness of the etch stop layer 750 for protecting the TFT 725 and the thickness of the dielectric material for adjusting the capacitance Cst of the storage capacitor 775. This can be done by having a first etch stop layer 750 and a second etch stop layer 755 protecting the TFT 725, and having only the second etch stop layer 755 as the dielectric material in the storage capacitor 775.

Alternatively, to achieve sufficient thickness for protecting the TFT and to achieve a high density storage capacitor with a controllable thickness, yet another implementation of an apparatus 800 including a TFT 825 and a storage capacitor 875 can be provided. FIG. 8 is an example of a cross-sectional diagram illustrating an apparatus 800 including a TFT 825 and a storage capacitor 875, a thickness of the storage capacitor 875 defined by a thickness of a dielectric layer 830 and a semiconductor layer 840 serving as an electrode according to some implementations. In the implementation as illustrated in FIG. 8, instead of removing the dielectric layer 830 over the second region of the substrate 810 as illustrated in FIG. 7, the dielectric layer 830 serves as the dielectric material for the storage capacitor 875. Moreover, the semiconductor layer 840 can be included as part of the storage capacitor 875 and can serve as part of an electrode in the storage capacitor 875. The implementation in FIG. 8 can be manufactured using fewer processing steps than the implementation in FIG. 7. In particular, manufacturing the implementation in FIG. 8 may use at least one less masking/photolithography step than manufacturing the implementation in FIG. 7.

The apparatus 800 in FIG. 8 can include a TFT 825 on the first region of the substrate 810 and a storage capacitor 875 on the second region of the substrate 810. The TFT 825 includes a first metal layer 820 on the substrate 810, a dielectric layer 830 on the first metal layer 825, a semiconductor layer 840 on the dielectric layer 830, an etch stop layer 850 on the semiconductor layer 840, and a second metal layer 860 contacting a source region and a drain region of the semiconductor layer 840. The semiconductor layer 840 can include a source region, a drain region, and a channel region between the source region and the drain region.

The storage capacitor 875 includes the first metal layer 820 on the substrate 810, the dielectric layer 830 on the first metal layer 820, the semiconductor layer 840 on the dielectric layer 830 over the second region of the substrate 810 where the semiconductor layer 840 has an exposed region and an unexposed region, and the etch stop layer 850 on the unexposed region of the semiconductor layer 840 and the second metal layer 860 on the exposed region of the semiconductor layer 840. In some implementations, the TFT 825 and the storage capacitor 875 can be part of a pixel of a display device. For example, an EMS display element (e.g., interferometric modulator) (not shown) can be disposed underneath the TFT 825 and the storage capacitor 875.

In FIG. 8, the apparatus 800 can include a substrate 810 having a first region and a second region adjacent to the first region. The apparatus 800 in FIG. 8 is described in terms of the cross-sectional diagram and in terms of a manufacturing process for fabricating the apparatus 800 in FIG. 8.

In manufacturing the apparatus 800 in FIG. 8, a substrate 810 may be provided having a first region and a second region adjacent to the first region. The substrate 810 may be any number of different substrate materials, including transparent materials and non-transparent materials. In some implementations, the substrate 810 is silicon, silicon-on-insulator (SOI), or a glass (e.g., a display glass or a borosilicate glass). A non-glass substrate can be used, such as a polycarbonate, acrylic, polyethylene terephthalate (PET), or polyether ether ketone (PEEK) substrate. In some implementations, the substrate 810 on which the TFT 825 is fabricated has dimensions of a few microns to hundreds of microns. The TFT 825 and the storage capacitor 875 may be co-fabricated on the substrate 810, where the TFT 825 is formed on the first region of the substrate 810 and the storage capacitor 875 can be formed on the second region of the substrate 810.

In some implementations, the apparatus 800 can include an EMS display element (not shown), where the substrate 810 is a buffer layer over the EMS display element. The TFT 825 and the storage capacitor 875 can be formed on the buffer layer and over the EMS display element.

The apparatus 800 can include a first metal layer 820 on the first region and the second region of the substrate 810. The first metal layer 820 can include any number of different metals, including Al, Cu, Mo, Ta, Cr, Nd, W, Ti, Au, Ni, and an alloy containing any of these elements. In some implementations, the first metal layer 820 can include a transparent metal oxide conducting layer, including ITO. In some implementations, the first metal layer 820 includes two or more sub-layers of different metals arranged in a stacked structure. In some implementations, the first metal layer 820 can have a thickness between about 50 nm and about 500 nm, or between about 100 nm and about 250 nm.

In manufacturing the apparatus 800 in FIG. 8, the first metal layer 820 may be formed on the first region and the second region of the substrate 810. Forming the first metal layer 820 can include steps of depositing, masking, and/or etching the first metal layer 820. The first metal layer 820 may be deposited using deposition processes as known by a person having ordinary skill in the art, including PVD processes, CVD processes, and ALD processes. PVD processes include thermal evaporation deposition, sputter deposition, and PLD. For example, the first metal layer 820 may include Mo and may be deposited using sputter deposition. In some implementations, the first metal layer 820 may be patterned so that a portion of the substrate 810 is exposed between the first region and the second region of the substrate 810. The first metal layer 820 may be patterned so that a portion of the first metal layer 820 is spaced apart from another portion of the first metal layer 820. The first metal layer 820 may be etched using a dry (e.g., plasma) etching process or a wet chemical etching process. The first metal layer 820 on the first region can serve as a gate for the TFT 825 and the first metal layer 820 on the second region can serve as an electrode for the storage capacitor 875.

The apparatus 800 can further include a dielectric layer 830 on the first metal layer 820 over the first region and the second region of the substrate 810. The dielectric layer 830 may include any number of different dielectric materials, including SiO₂, Al₂O₃, HfO₂, TiO₂, SiON, or SiN. In some implementations, the dielectric layer 830 includes two or more sub-layers of different dielectric materials arranged in a stacked structure. In some implementations, a thickness of the dielectric layer 830 can be between about 50 nm and about 500 nm, or between about 100 nm and about 250 nm.

In manufacturing the apparatus 800 in FIG. 8, the dielectric layer 830 may be formed on the first metal layer 820 over the first region and the second region of the substrate 810. The dielectric layer 830 may be deposited using deposition processes as known by a person having ordinary skill in the art, including PVD processes, CVD processes including PECVD processes, and ALD processes. For example, the dielectric layer 830 may include SiO₂ deposited using a PECVD process at a processing temperature greater than about 300° C. The dielectric layer 830 may be continuous over the first metal layer 820 and the substrate 810. The dielectric layer 830 may serve as a gate insulator for the TFT 825 and as a dielectric for the storage capacitor 875. Thus, in contrast to FIG. 7, the apparatus 800 in FIG. 8 leaves the dielectric layer 830 with the storage capacitor 875.

The apparatus 800 can further include a semiconductor layer 840 on the dielectric layer 830 over the first region and the second region of the substrate 810. The semiconductor layer 840 can be an oxide semiconductor layer. In some implementations, the oxide semiconductor layer includes an amorphous oxide semiconductor, including indium-containing, zinc-containing, tin-containing, hafnium-containing, and gallium-containing oxide semiconductors. Specific examples of amorphous oxide semiconductors include InGaZnO, InZnO, InHfZnO, InSnZnO, SnZnO, InSnO, GaZnO, and ZnO. In some implementations, the channel region of the semiconductor layer 840 may be aligned with the patterned first metal layer 820. The channel region may be between a source region and a drain region of the semiconductor layer 840. In some implementations, the semiconductor layer 840 is about 10 to about 100 nm thick.

In manufacturing the apparatus 800 in FIG. 8, the semiconductor layer 840 can be formed on the dielectric layer 830 over the first region and the second region of the substrate 810. The semiconductor layer 840 can include a source region, a drain region, and a channel region between the source region and the drain region. Forming the semiconductor layer 840 can include steps of depositing, masking, and/or etching the semiconductor layer 840. In some implementations, the semiconductor layer 840 is deposited with a PVD process. PVD processes include PLD, sputter deposition, e-beam PVD, and evaporative deposition. For example, the semiconductor layer 840 may include InGaZnO and may be deposited using sputter deposition. In some implementations, the semiconductor layer 840 may be patterned to expose portions of the dielectric layer 830 between the first region and the second region of the substrate 810, thereby leaving at least part of the semiconductor layer 840 over the first region and the second region intact. Hence, the semiconductor layer 840 may be patterned so that a portion of the semiconductor layer 840 may be spaced apart from another portion of the semiconductor layer 840. The semiconductor layer 840 may be etched using a dry (e.g., plasma) etching process or a wet chemical etching process, depending in part on the material of the semiconductor layer 840. The semiconductor layer 840 may serve as a semiconductor for the TFT 825 and at least part of the semiconductor layer 840 may be electrically conductive for the storage capacitor 875. Hence, in contrast to FIG. 7, the apparatus 800 in FIG. 8 leaves the semiconductor layer 840 with the storage capacitor 875. Furthermore, the semiconductor layer 840 can serve as an etch stopper, for instance, where the semiconductor layer 840 is an oxide semiconductor having a high selectivity against dry etching.

The apparatus 800 can further include an etch stop layer 850 on the semiconductor layer 840 over the first region of the substrate 810. The etch stop layer 850 can include any suitable dielectric materials. In some implementations, the etch stop layer 850 can be made of the same material as the dielectric layer 830. For example, the etch stop layer 850 and the dielectric layer 830 can be made of SiO₂. In some implementations, the etch stop layer 850 is between about 50 nm and about 500 nm thick.

In manufacturing the apparatus 800 in FIG. 8, the etch stop layer 850 may be formed on the semiconductor layer 840 over the first region and the second region of the substrate 810. Forming the etch stop layer 850 can include steps of depositing, masking, and/or etching the etch stop layer 850. The etch stop layer 850 may be deposited using deposition processes as known by a person having ordinary skill in the art, including PVD processes, CVD processes including PECVD processes, and ALD processes. For example, the etch stop layer 850 can include SiO₂ deposited using a PECVD process at a processing temperature less than about 250° C.

In some implementations, one or more first openings may be formed extending through the etch stop layer 850 to the semiconductor layer 840 over the second region of the substrate 810. Portions of the etch stop layer 850 over the second region of the substrate 810 may be removed to expose at least a part of the semiconductor layer 840 over the second region of the substrate 810. The unexposed parts of the semiconductor layer 840 may remain covered by the etch stop layer 850. The one or more first openings may be formed using etching processes as known by a person having ordinary skill in the art. For example, the etch stop layer 850 may be etched using dry etching, including CF₄ or C₄F₈ as the main etching gas. The underlying semiconductor layer 840 may be highly selective against dry etching.

In some implementations, portions of the etch stop layer 850 and the dielectric layer 830 outside the first region and the second region of the substrate 810 may be removed to allow for electrical interconnection with the first metal layer 820 on the first region of the substrate 810. Though not shown in FIG. 8, removal of the etch stop layer 850 and the dielectric layer 830 outside the first region and the second region of the substrate 810 can permit an electrically conductive pathway to be formed between a source/drain and a gate of the TFT 825. In some implementations, this processing step can occur concurrently with the removal of portions of the etch stop layer 850 over the second region of the substrate 810.

In addition, one or more second openings may be formed extending through the etch stop layer 850 to the semiconductor layer 840 over the first region of the substrate 810. Portions of the etch stop layer 850 over the first region of the substrate 810 may be removed to expose parts of the semiconductor layer 840 over the first region of the substrate 810. The one or more second openings can expose the source region and the drain region of the semiconductor layer 840. The exposed parts of the semiconductor layer 840 may serve as terminals for source and drain contacts in the TFT 825. Another part of the semiconductor layer 840 may remain covered by the etch stop layer 850. The covered part of the semiconductor layer 840 may be aligned with the channel region of the semiconductor layer 840. Portions of the etch stop layer 850 may be removed using etching processes as known by a person having ordinary skill in the art. In some implementations, the formation of the one or more second openings can occur concurrently with the formation of the one or more first openings. In some implementations, the formation of the one or more second openings can occur concurrently with the removal of portions of the etch stop layer 850 and the dielectric layer 830 outside of the first region and the second region of the substrate 810. Though the etch depth during this processing step can include the thicknesses of the etch stop layer 850 and the dielectric layer 830, the semiconductor layer 840 can be selective against etching during the processing step.

The apparatus 800 may further include a second metal layer 860 on the semiconductor layer 840 in the one or more first openings and on the semiconductor layer 840 in the one or more second openings. The second metal layer 860 may be contacting the semiconductor layer 840 at the source region and the drain region. In some implementations, the second metal layer 860 can include a source terminal 860a and a drain terminal 860b, where the source terminal 860a contacts the source region of the semiconductor layer 840 and the drain terminal 860b contacts the drain region of the semiconductor layer 840.

The second metal layer 860 can include any number of different metals, including Al, Cu, Mo, Ta, Cr, Nd, W, Ti, Ni, Au, and an alloy containing any of these elements. In some implementations, the second metal layer 860 can include a transparent metal oxide conducting layer, including ITO. In some implementations, the second metal layer 860 includes two or more sub-layers of different metals arranged in a stacked structure. In some implementations, the second metal layer 860 can have a thickness between about 50 nm and about 500 nm, or between about 100 nm and about 250 nm.

In manufacturing the apparatus 800 in FIG. 8, the second metal layer 860 may be formed on the semiconductor layer 840 in the one or more first openings and on the semiconductor layer 840 in the one or more second openings. Forming the second metal layer 860 can include steps of depositing, masking, and/or etching the second metal layer 860. In some implementations, the second metal layer 860 may be formed on the source region and the drain region of the semiconductor layer 840 over the first region of the substrate 810. The second metal layer 860 may fill or at least substantially fill the one or more first openings and the one or more second openings. The second metal layer 860 may be deposited using deposition processes as known by a person having ordinary skill in the art, including PVD processes, CVD processes, and ALD processes. In some implementations in which the second metal layer 860 is formed using a PVD process, the PVD process is sputter deposition, e-beam PVD, or evaporative deposition. The second metal layer 860 may be etched using a dry (e.g., plasma) etching process or a wet chemical etching process. The second metal layer 860 can serve as the source/drain metal for the TFT 825 over the first region of the substrate 810. Furthermore, the second metal layer 860 on the semiconductor layer 840 in the one or more first openings can allow the semiconductor layer 840 to function as one of the electrodes for the storage capacitor 875 over the second region of the substrate 810. The exposed part of the semiconductor layer 840 can be in direct electrical contact with the second metal layer 860 so that the semiconductor layer 840 behaves like an electrode. The exposed semiconductor layer 840 in contact with the second metal layer 860 is electrically conductive.

With respect to the TFT 825, the second metal layer 860 contacting the source region of the semiconductor layer 840 can be configured to output an output signal, where the output signal can be configured to drive a display element, such as an EMS display element. With respect to the storage capacitor 875, the second metal layer 860 contacting the semiconductor layer 840 at the drain region can be configured to receive an input signal, where the input signal can cause charge to be accumulated along the semiconductor layer 840 over the second region of the substrate 810. The input signal can store data in the storage capacitor 875 for the display device.

The implementation as illustrated in FIG. 8 can reduce the number of processing steps compared to FIG. 7 while achieving a sufficient capacitance Cst for the storage capacitor 875. The thickness of the dielectric of the storage capacitor 875 can correspond directly to the thickness of the dielectric layer 830 (e.g., gate insulator of the TFT 825). The semiconductor layer 840 can serve as an etch stopper and as an electrode for the storage capacitor 875 when electrically connected to the second metal layer 860 (e.g., source/drain of the TFT 825).

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
substrate having a first region and a second region adjacent to the first region;
a thin film transistor (TFT) on the first region of the substrate, the TFT including:
a first metal layer on the substrate,
a semiconductor layer over the first metal layer, the semiconductor layer having a channel region between a source region and a drain region,
a first etch stop layer on the semiconductor layer,
a second etch stop layer on the first etch stop layer, and
a second metal layer contacting the source region and the drain region of the semiconductor layer; and
a storage capacitor on the second region of the substrate, the storage capacitor including:
the first metal layer on the substrate,
the second etch stop layer on the first metal layer over the second region of the substrate, and
the second metal layer on the second etch stop layer over the second region of the substrate.

2. The apparatus of claim 1, further comprising:
a dielectric layer between the first metal layer and the semiconductor layer over the first region of the substrate, wherein each of the dielectric layer and the first etch stop layer includes silicon dioxide.

3. The apparatus of claim 1, wherein each of the first etch stop layer and the second etch stop layer includes silicon dioxide.

4. The apparatus of claim 1, wherein the semiconductor layer includes indium-gallium-zinc-oxide (InGaZnO).

5. The apparatus of claim 1, wherein the substrate includes glass.

6. The apparatus of claim 1, further comprising:
an electromechanical systems (EMS) display element, wherein the substrate is a buffer layer over the EMS display element.

7. The apparatus of claim 1, wherein the second etch stop layer has a thickness less than about 100 nm.

8. The apparatus of claim 1, further comprising:
one or more first openings extending through the first etch stop layer to the first metal layer on the second region of the substrate; and
one or more second openings extending through the first etch stop layer and the second etch stop layer to the source region and the drain region of the semiconductor layer.

9. The apparatus of claim 8, wherein the second metal layer substantially fills the one or more first openings and the one or more second openings.

10. The apparatus of claim 8, wherein the second etch stop layer is conformal along sidewalls of the one or more first openings extending through the first etch stop layer.

11. The apparatus of claim 1, wherein the second metal layer contacts the semiconductor layer at the source region and is configured to output an output signal to drive an EMS display element.

12. The apparatus of claim 1, wherein the second metal layer contacts the semiconductor layer at the drain region and is configured to receive an input signal, wherein the input signal causes charge to be accumulated along the second metal layer on the second etch stop layer over the second region of the substrate.

13. An apparatus comprising:
a substrate having a first region and a second region adjacent to the first region;
a thin film transistor (TFT) on the first region of the substrate, the TFT including:
a first metal layer on the substrate,
a dielectric layer on the first metal layer,
a semiconductor layer on the dielectric layer, and
an etch stop layer on the semiconductor layer; and
a storage capacitor on the second region of the substrate, the storage capacitor including:
the first metal layer on the substrate,
the dielectric layer on the first metal layer,
the semiconductor layer on the dielectric layer, the semiconductor layer over the second portion of the substrate having an exposed region and an unexposed region,
the etch stop layer on the unexposed region of the semiconductor layer, and
a second metal layer on the exposed region of the semiconductor layer.

14. The apparatus of claim 13, wherein each of the dielectric layer and the etch stop layer includes silicon dioxide.

15. The apparatus of claim 13, wherein the semiconductor layer includes indium-gallium-zinc-oxide (InGaZnO).

16. The apparatus of claim 13, wherein the substrate includes glass.

17. The apparatus of claim 13, further comprising:
an electromechanical systems (EMS) display element, wherein the substrate is a buffer layer over the EMS display element.

18. The apparatus of claim 13, wherein the dielectric layer has a thickness between about 50 nm and about 500 nm.

19. The apparatus of claim 13, wherein the semiconductor layer has a channel region between a source region and a drain region over the first region of the substrate, the apparatus further comprising:
one or more first openings extending through the etch stop layer to the exposed region of the semiconductor layer; and
one or more second openings extending through the etch stop layer to the source region and the drain region of the semiconductor layer.

20. The apparatus of claim 19, wherein the second metal layer substantially fills the one or more first openings and the one or more second openings.

21. The apparatus of claim 19, wherein the second metal layer contacts the semiconductor layer at the source region and is configured to output an output signal to drive an EMS display element.

22. The apparatus of claim 19, wherein the second metal layer contacts the semiconductor layer at the drain region and is configured to receive an input signal, wherein the input signal causes charge to be accumulated along the semiconductor layer over the second region of the substrate.

23. The apparatus of claim 13, wherein the exposed region of the semiconductor layer in contact with the second metal layer is electrically conductive.

24. A method of manufacturing a TFT and a storage capacitor on a substrate, the method comprising:
providing a substrate having a first region and a second region adjacent to the first region;
forming a first metal layer on the first region and the second region of the substrate;
forming a dielectric layer on the first metal layer over the first region and the second region of the substrate;
forming a semiconductor layer on the dielectric layer over the first region of the substrate, the semiconductor layer having a channel region between a source region and a drain region;
forming a first etch stop layer on the semiconductor layer over the first region of the substrate and on the dielectric layer over the second region of the substrate;
forming one or more first openings extending through the etch stop layer and the dielectric layer to the first metal layer over the second region of the substrate;
forming a second etch stop layer on the first etch stop layer over the first region of the substrate and in the one or more first openings and on the first metal layer over the second region of the substrate;
forming one or more second openings extending through the second etch stop layer and the first etch stop layer to the source region and the drain region of the semiconductor layer; and
forming a second metal layer on the second etch stop layer in the one or more first openings and on the source region and the drain region of the semiconductor layer in the one or more second openings.

25. The method of claim 24, wherein the second metal layer on the source region is configured to output an output signal to drive an EMS display element, and wherein the second metal layer on the drain region of the semiconductor layer is configured to receive an input signal to cause charge to be accumulated along the second metal layer over the second region of the substrate.

26. The method of claim 24, wherein the second etch stop layer has a thickness of less than about 100 nm.

27. A method of manufacturing a TFT and a storage capacitor on a substrate, the method comprising:
providing a substrate having a first region and a second region adjacent to the first region;
forming a first metal layer on the first region and the second region of the substrate;
forming a dielectric layer on the first metal layer over the first and the second region of the substrate;
forming a semiconductor layer on the dielectric layer over the first region and the second region of the substrate, the semiconductor layer over the first region having a channel region between a source region and a drain region;
forming an etch stop layer on the semiconductor layer over the first region and the second region of the substrate;
forming one or more first openings extending through the etch stop layer to expose a portion of the semiconductor layer over the second region of the substrate;
forming one or more second openings extending through the etch stop layer to expose the source region and the drain region of the semiconductor layer over the first region of the substrate; and
forming a second metal layer on the semiconductor layer in the one or more first openings and on the semiconductor layer in the one or more second openings, the semiconductor layer in contact with the second metal layer in the one or more first openings being electrically conductive.

28. The method of claim 27, wherein the second metal layer at the source region is configured to output an output signal to drive an EMS display element, and wherein the second metal layer at the drain region is configured to receive an input signal to cause charge to be accumulated along the semiconductor layer over the second region of the substrate.

29. The method of claim 27, wherein the dielectric layer has a thickness between about 50 nm and about 500 nm.
